(19) United States
(12) Patent Application Publication
(10) Pub. No.: US 2025/0023331 A1
(43) Pub. Date: Jan. 16, 2025

(54) SEMICONDUCTOR LASER

(71) Applicant: Lumentum Operations LLC, San Jose, CA (US)

(72) Inventor: Atsushi NAKAMURA, Komoro (JP)

(21) Appl. No.: 18/396,428

(22) Filed: Dec. 26, 2023

(30) Foreign Application Priority Data
Jul. 12, 2023 (JP) 2023-114263
Sep. 8, 2023 (JP) 2023-146509

(51) Int. Cl. H01S 5/227; H01S 5/028; H01S 5/042; H01S 5/0625; H01S 5/10; H01S 5/12

(52) U.S. Cl. CPC H01S 5/227; H01S 5/0287; H01S 5/042; H01S 5/06258; H01S 5/1014; H01S 5/1228

(57) ABSTRACT

To provide a semiconductor laser with which a high light output characteristic and reduction in occurrence of a lateral high-order mode can be achieved, the semiconductor laser includes a diffraction grating layer including first and second refractive index regions. A mesa structure includes a first region having a first width and a second region having a second width wider than the first width. The first region includes a diffraction grating region in which the first and second refractive index regions for use in reflecting a light beam having a Bragg wavelength are alternately arranged at the same period. The second region includes a diffraction grating region and a non-diffraction grating region. The diffraction grating region of the first region and the diffraction grating region of the second region form a resonator. A normalized coupling coefficient of the first region is larger than a normalized coupling coefficient of the second region.

### CROSS-REFERENCE TO RELATED APPLICATION

This patent application claims priority to Japanese Patent Application number 2023-146509 filed on Sep. 8, 2023, and Japanese Patent Application number 2023-114263 filed on Jul. 12, 2023. The disclosure of the prior applications is considered part of and is incorporated by reference into this patent application.

### TECHNICAL FIELD

The present disclosure relates generally to a semiconductor laser.

### BACKGROUND

Semiconductor lasers are widely used as a light source in optical communications. A distributed feedback semiconductor laser (DFB laser) is one type of a semiconductor laser. In many cases, the DFB laser includes a diffraction grating. Further, a structure in which a phase shift portion is included in the diffraction grating can be used for characteristic improvement. A stable single-wavelength operation can be obtained by forming an anti-reflection film (e.g., a low reflection film) on both facets of the semiconductor laser and arranging a λ/4 shift portion in the diffraction grating. A reflectance with respect to a Bragg-reflected light beam can be changed between a front and a rear of the phase shift portion so that output from one facet is increased.

Further, a structure in which the diffraction grating is removed at a particular period to adjust a coupling coefficient κ can be used.

### SUMMARY

A semiconductor laser often includes a mesa structure for the purpose of locally concentrating currents injected for drive. A region in which currents are injected can be limited by narrowing a width of the mesa structure in a direction perpendicular to a direction in which the mesa structure extends (hereinafter referred to as “mesa width”). It is effective to increase the mesa width in order to increase the light output. When the mesa width is increased, a width of an active layer to be effectively driven is increased, and thus high light output can be obtained.

The mesa width also plays a role in determining a mode of a light beam propagating through a waveguide. When the mesa width is narrow, only a basic mode propagates in a lateral mode, but a lateral high-order mode can also propagate when the mesa width is increased. Light output including the lateral high-order mode is undesired as a light source for optical communications. When the mesa width is increased in order to increase the light output as described above, the lateral high-order mode occurs, which leads to reduction in continuity of currents and a light output characteristic, that is, occurrence of so-called kinks, which is not preferred as the light source for communications.

Some implementations described herein provide a semiconductor laser that enables a high light output characteristic and a reduction in occurrence of a lateral high-order mode.

In some implementations, a semiconductor laser includes: a substrate; an active layer formed in or under a mesa structure formed on the substrate; a cladding layer formed above the active layer formed in the mesa structure; a diffraction grating layer formed in the cladding layer, the diffraction grating layer including a plurality of first refractive index regions and a plurality of second refractive index regions; and a low-reflection facet coating film provided on both facets in a direction in which the mesa structure extends, wherein the mesa structure includes, in plan view, a first region having a first width and a second region having a second width that is wider than the first width, wherein the first region includes a first diffraction grating region in which the plurality of first refractive index regions and the plurality of second refractive index regions for use in reflecting a light beam having a Bragg wavelength are alternately arranged, wherein the second region includes a second diffraction grating region in which the plurality of first refractive index regions and the plurality of second refractive index regions are alternately arranged, and a non-diffraction grating region which transmits the light beam having the Bragg wavelength, wherein the first diffraction grating region and the second diffraction grating region form a resonator, and wherein the first region has a normalized coupling coefficient that is larger than a normalized coupling coefficient of the second region.

### BRIEF DESCRIPTION OF THE DRAWINGS

FIG. 1 is a top view for illustrating a semiconductor laser according to a first example implementation of the present invention.

FIG. 2 is a schematic sectional view taken along the line II-II of the semiconductor laser illustrated in FIG. 1.

FIG. 3 is a schematic sectional view taken along the line III-III of the semiconductor laser illustrated in FIG. 1.

FIG. 4 is a schematic sectional view taken along the line IV-IV of the semiconductor laser illustrated in FIG. 1.

FIG. 5 is a top view for illustrating the semiconductor laser according to the first example implementation.

FIG. 6 is a top view for illustrating a semiconductor laser according to a modification example of the first example implementation.

FIG. 7 is a top view for illustrating a semiconductor laser according to a second example implementation of the present invention.

FIG. 8 is a schematic sectional view taken along the line VIII-VIII of the semiconductor laser illustrated in FIG. 7.

FIG. 9 is a top view for illustrating a semiconductor laser according to a third example implementation of the present invention.

FIG. 10 is a top view for illustrating a semiconductor laser according to a fourth example implementation of the present invention.

FIG. 11 is a schematic sectional view for illustrating the semiconductor laser according to the fourth example implementation.

FIG. 12 is a top view for illustrating a semiconductor laser according to a modification example of the fourth example implementation.

### DETAILED DESCRIPTION

The following detailed description of example implementations refers to the accompanying drawings. The same reference numbers in different drawings may identify the same or similar elements. Sizes in the drawings may not correspond to scale.

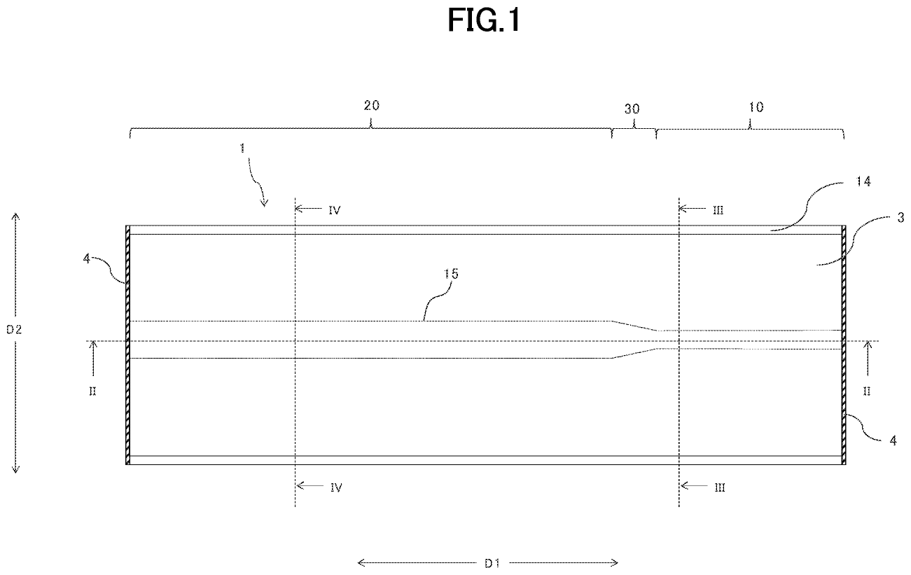

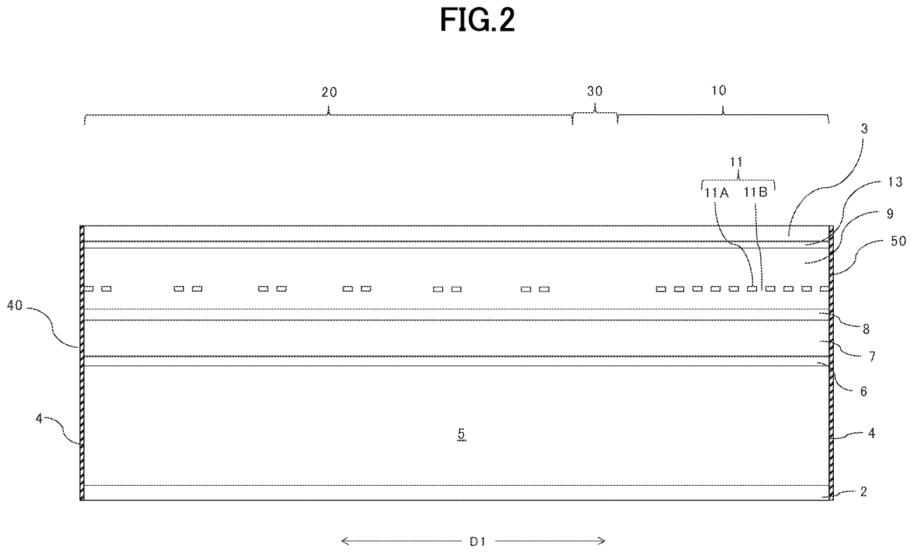

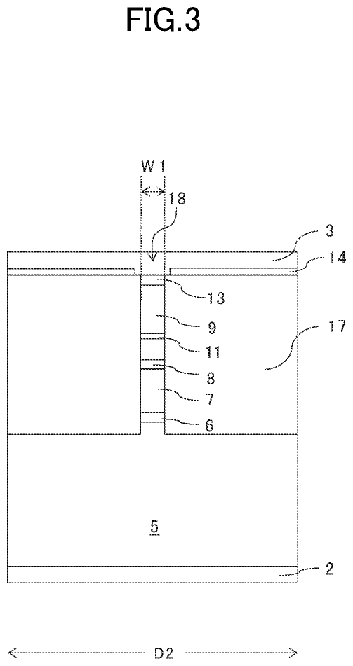

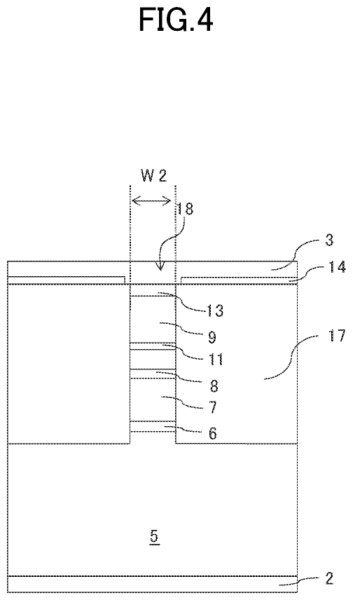

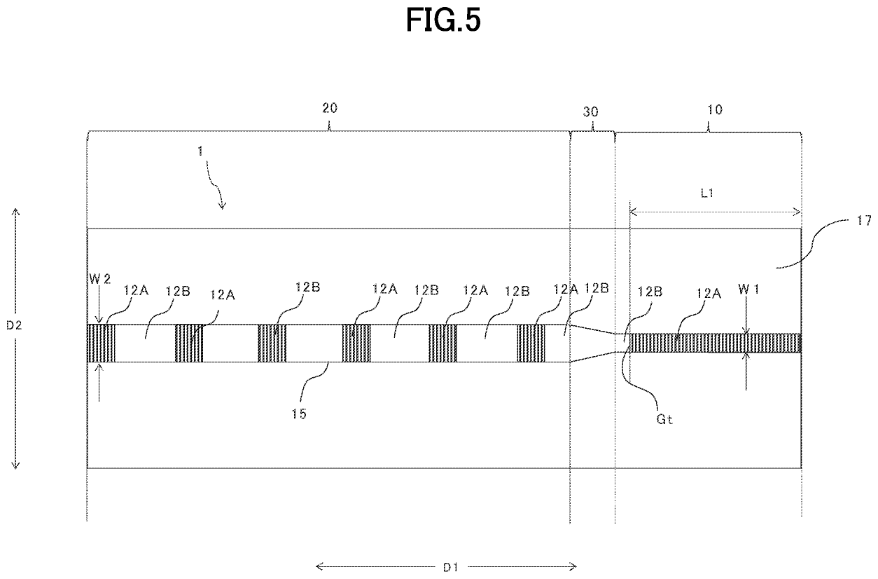

FIG. 1 is a top view for illustrating a semiconductor laser 1 according to a first example implementation of the present invention. FIG. 2 shows a schematic sectional view taken along the line II-II of FIG. 1. FIG. 3 shows a schematic sectional view taken along the line III-III of FIG. 1. FIG. 4 shows a schematic sectional view taken along the line IV-IV of FIG. 1. FIG. 5 is a top view for illustrating the semiconductor laser 1, and is an explanatory view for illustrating a position of each region included in the semiconductor laser 1.

The semiconductor laser 1 may include a first electrode 2 on a back surface thereof and a second electrode 3 on a front surface thereof. The first electrode 2 and the second electrode 3 may be metal layers. A light beam may emit from a front facet 40 (e.g., a facet on the left side of the semiconductor laser 1 in FIG. 1) through injection of currents between the first electrode 2 and the second electrode 3. A low-reflection facet coating film 4 may be formed on both facets of the semiconductor laser 1 in a direction in which a mesa structure to be described later extends, that is, on the front facet 40 and a rear facet 50 (e.g., a facet on the right side of the semiconductor laser 1 in FIG. 1). The low-reflection facet coating film 4 may have a reflectance of 1% or less.

The semiconductor laser 1 may include a semiconductor layer in which an optical confinement layer (e.g., a separate confinement heterostructure (SCH) layer) 6 of a first conductivity type, an active layer 7, an optical confinement layer 8 (e.g., a SCH layer) of a second conductivity type, a cladding layer 9 of the second conductivity type, and a contact layer 13 of the second conductivity type may be grown in the stated order on a substrate 5 of the first conductivity type. Further, the cladding layer 9 of the second conductivity type may have a diffraction grating layer 11 formed therein. The semiconductor laser 1 may be a DFB laser. The active layer 7 may be formed of, for example, a multiple-quantum well layer. Further, the multiple-quantum well layer may be an intrinsic semiconductor or an n-type semiconductor. In this case, the first conductivity type may be an n-type and the second conductivity type may be a p-type, but the first conductivity type may be the p-type and the second conductivity type may be the n-type. Further, the semiconductor layer including the above-mentioned layers may include a mesa structure 15. For example, the active layer 7 may be formed in the mesa structure formed on the substrate 5, and the cladding layer 9 may be formed above the active layer 7 formed in the mesa structure 15. The mesa structure 15 may extend in a light extraction direction (first direction D1). A lower portion of the mesa structure 15 may be a part of the substrate 5. Both sides of the mesa structure 15 may be covered with a semiconductor buried layer 17 having a semi-insulating property. The buried layer 17 may be a stack formed of semiconductor layers of the p-type and the n-type. The dotted lines of FIG. 1 indicate positions of boundaries between an upper portion of the mesa structure 15 and the buried layer 17.

The semiconductor laser 1 may include an insulating film 14 on the front surface thereof. The insulating film 14 may cover the front surface of the semiconductor laser 1 except for a part of the front surface. The insulating film 14 may include an opening (e.g., a through hole) 18 in a region corresponding to the upper portion of the mesa structure 15. The second electrode 3 and the contact layer 13 of the second conductivity type may be connected to each other via the through hole 18, and electric signals may be applied (currents may be injected) to the semiconductor layer including the mesa structure 15. Here, the through hole 18 may be formed along the first direction D1. Further, in a second direction D2 perpendicular to the first direction D1, a width of the through hole 18 may be wider than a width of the mesa structure 15. However, the through hole 18 and the mesa structure 15 may have the same width.

The diffraction grating layer 11 may include a plurality of first refractive index regions and a plurality of second refractive index regions. Specifically, the diffraction grating layer 11 may be of a floating type, and may be formed of, in sectional view, regions having a first refractive index that may be different from a refractive index of the cladding layer 9 of the second conductivity type, and regions having a second refractive index in which the cladding layer 9 of the second conductivity type may be arranged. That is, the diffraction grating layer 11 may have a structure in which first refractive index regions 11A and second refractive index regions 11B are alternately arranged. In this case, the first refractive index may be higher than the second refractive index, or, alternatively, the second refractive index may be higher than the first refractive index.

The mesa structure 15 may have regions with widths that vary along the direction in which the first direction D1 extends, such as in the second direction D2 perpendicular to the first direction D1. The width of the mesa structure 15 in the second direction D2 may be hereinafter referred to as “mesa width.” The semiconductor laser 1 may include a first region 10 in which the mesa width is W1, and a second region 20 in which the mesa width is W2. Here, W2 may be wider than W1. That is, the mesa structure may include, in plan view, a first region having a first width, and a second region having a second width wider than the first width. Further, the mesa structure 15 may include, between the first region 10 and the second region 20, a third region 30 having a mesa width that gradually changes from W1 to W2. The second electrode 3 may be integrally arranged across the first region 10, the second region 20, and the third region 30. The second electrode 3 may be individually arranged in each of the regions, or, such as in this case, it may be desired that each electrode individually arranged be connected to the same power supply.

FIG. 5 is a top view for illustrating the semiconductor laser 1, and is an explanatory view for illustrating a position of each region included in the diffraction grating layer 11. For the sake of description, part of elements is not shown. A region in the diffraction grating layer 11 in which the first refractive index regions 11A and the second refractive index regions 11B may be alternately arranged at the same period is referred to as “diffraction grating region 12A.” Meanwhile, a region in the diffraction grating layer 11 in which only the first refractive index region 11A or only the second refractive index region 11B is arranged is referred to as “non-diffraction grating region 12B.” In the first example implementation, the non-diffraction grating region 12B may be formed of the second refractive index region 11B. In the first region 10, the diffraction grating layer 11 may have one diffraction grating region 12A arranged therein. The diffraction grating region 12A in the first example implementation may have a uniform diffraction grating structure in which the first refractive index regions 11A and the second refractive index regions 11B may be alternately arranged at the same period along the first direction D1. That is, the first region 10 may include a diffraction grating region in which the first refractive index regions 11A and the second refractive index regions 11B for use in reflecting a light beam having a Bragg wavelength are alternately arranged at the same period. The Bragg wavelength of this diffraction grating corresponds to a 1.3-micrometer (μm) band, but other Bragg wavelengths such as a 1.55-μm band may be used. The first region 10 may include the non-diffraction grating region 12B on a side closer to a portion connected to the third region 30. The first region 10 may not include the non-diffraction grating region 12B, and the diffraction grating region 12A may be arranged in the entire first region 10.

In the second region 20, the diffraction grating regions 12A and the non-diffraction grating regions 12B may be alternately arranged. Here, the diffraction grating regions 12A and the non-diffraction grating regions 12B may be arranged so that the light beam having the Bragg wavelength transmitted from the first region 10 may be reflected into the second region 20. In order to strongly reflect a light beam having a specific wavelength (e.g., a Bragg wavelength), adjustment of periods (diffraction grating periods) of the first refractive index regions 11A and the second refractive index regions 11B may be used. Further, a relationship between the diffraction grating period and the Bragg wavelength may be dependent on an effective refractive index. In the first example implementation, the second region 20 may have a wider mesa width as compared to the first region 10, and hence may have a larger effective refractive index. However, at the same time, when the second region 20 is viewed as a whole, the number of regions having no diffraction grating structure (regions being the non-diffraction grating regions 12B) may be large, and hence the effective refractive index may be decreased by this amount. An average effective refractive index of the entire second region 20 may be determined by, as a total, both of an amount of increase of the effective refractive index achieved by increasing the mesa width and an amount of decrease of the effective refractive index caused by not arranging the diffraction grating structure. In consideration of a difference between the average effective refractive index of the first region 10 and the average effective refractive index of the second region 20, the diffraction grating regions 12A and the non-diffraction grating regions 12B to be arranged in the second region 20 may be determined. Here, the diffraction grating period of the diffraction grating region 12A in the second region 20 may be different from or the same as the diffraction grating period of the diffraction grating region 12A in the first region 10. In the case of employing the same diffraction grating period, it may be only required to adjust a length in the first direction D1 of each of the plurality of diffraction grating regions 12A and the plurality of non-diffraction grating regions 12B and intervals of both of those regions so that the average diffraction grating period of the entire second region 20 reflects the light beam having the desired Bragg wavelength. In the following, when particular distinction may be required, the diffraction grating region 12A included in the first region 10 may be referred to as a “first diffraction grating region,” and the diffraction grating region 12A included in the second region 20 may be referred to as a “second diffraction grating region.” The diffraction grating regions 12A and the non-diffraction grating regions 12B included in the second region 20 may have different lengths in the first direction D1. in some implementations, for example, under a condition of causing reflection at a desired Bragg wavelength, each length may be different so as to suppress high-order diffraction backscattering with respect to the Bragg wavelength.

In order to obtain a high single mode oscillation, a resonator may be formed by the first region 10 and the second region 20. In order to form the resonator by the first region 10 and the second region 20, it may be required that a phase of the diffraction grating region of the first region 10 and a phase of the diffraction grating region of the second region 20 be x-shifted. Here, the phase of the diffraction grating region refers to a phase of the diffraction grating structure. For example, when the first region 10 and the second region 20 have the same effective refractive index, the phase of the second diffraction grating region (diffraction grating region 12A of the second region 20) may be x-shifted with respect to the phase of the first diffraction grating region (diffraction grating region 12A of the first region 10). However, in the first example implementation, the first region 10 and the second region 20 may have different effective refractive indices. Accordingly, the phase of the second diffraction grating region may be different from a phase obtained by x-shifting the phase of the first diffraction grating region. In the first example implementation, the phase of the first diffraction grating region and the phase of the second diffraction grating region may be not x-shifted, but the resonator may be formed by the first region 10 and the second region 20. Moreover, in the first example implementation, the low-reflection facet coating film 4 may be formed on both facets, and hence a single mode oscillation may be achieved. The second electrode 3 may be arranged across the first region 10 and the second region 20, and thus the first region 10 and the second region 20 may have substantially the same level of change of the effective refractive index depending on the injected current amount. Thus, a single mode oscillation may be achieved under a wide operating condition.

In the first example implementation, a normalized coupling coefficient κ1L1 of the first region 10 may be larger than a normalized coupling coefficient κ2L2 of the second region 20. Here, in some implementations, a coupling coefficient κ1 of the first region 10 and a coupling coefficient κ2 of the second region 20 may not be the same due to the difference in the mesa width, for example. However, this difference may be small, and the dominant cause of the difference in the normalized coupling coefficient between the first region 10 and the second region 20 may be the length in the first direction D1 of the diffraction grating region 12A included in each of the regions. Here, a length L1 of the first region 10 may be a length of the first diffraction grating region. That is, the length L1 of the first region 10 may not be a length of a region having the mesa width of W1, but a length of a region in which the diffraction grating region 12A may be arranged. A length L2 of the second region 20 may be a total length of the plurality of second diffraction grating regions. The non-diffraction grating region 12B may not reflect the light beam having the Bragg wavelength, and hence a coupling coefficient κ thereof may be practically regarded as 0. Accordingly, the length L2 contributing to the normalized coupling coefficient κL becomes the total length of the regions in which the plurality of second diffraction grating regions may be arranged. The normalized coupling coefficient κ1L1 of the first region 10 may be larger than the normalized coupling coefficient κ2L2 of the second region 20, and hence the light output intensity of the light beam output from the front facet 40 becomes larger than the light output intensity of the light beam output from the rear facet 50. When the normalized coupling coefficients of the first region 10 and the second region 20 are the same value, the light output intensities of the light beams output from the front facet 40 and the rear facet 50 may be the same. In some implementations, the total length of the regions in which the plurality of second diffraction grating regions are arranged may be set to be shorter than the length of the region in which the first diffraction grating region is arranged so that the intensity of the light beam output from the front facet 40 is increased. The “front” and the “rear,” as used here, are merely naming conventions used for the sake of convenience, and a facet having a larger light output may be referred to as the front facet. In a general optical communication, a larger light intensity is often preferred, and a light beam from the front facet may be used for the communication. Further, the total length in the first direction D1 of the plurality of second diffraction grating regions may be shorter than the total length of the plurality of non-diffraction grating regions 12B. With this structure, the effect of increasing the light output from the front side by decreasing the coupling coefficient κ2 of the second region 20 may be enhanced.

The third region 30 may include no diffraction grating region 12A. However, the third region 30 may include, in the vicinity of a portion connected to the first region 10, the same diffraction grating structure as that of the diffraction grating region 12A arranged in the first region 10. Similarly, the third region 30 may include, in the vicinity of a portion connected to the second region 20, the same diffraction grating structure as that of the diffraction grating region 12A arranged in the second region 20. When the diffraction grating region 12A is arranged in the entire third region 30, the width of each of the first refractive index regions 11A and the second refractive index regions 11B and the intervals of both of those regions may be adjusted in accordance with the change of the effective refractive index accompanying the change of the mesa width.

The mesa width W1 of the first region 10 may be set to be equal to or smaller than a width which causes no lateral high-order mode with respect to the light having the Bragg wavelength. In other words, W1 may be set to be equal to or smaller than a cut-off width. For example, W1 may be 2 μm or less. Further, in some cases, the occurrence condition of the lateral high-order mode may change depending on the drive condition. In order to stably obtain the effect of suppressing the lateral high-order mode, it may be preferred that W1 be equal to or smaller than 1.5 times the Bragg wavelength. For example, when the Bragg wavelength is 1.3 μm, W1 may be preferred to be 1.95 μm or less.

The mesa width W2 of the second region 20 may be wider than W1. The mesa width W2 may be greater than or equal to 1.2 times W1, or may be greater than or equal to 1.5 times W1. Further, W2 may be may be greater than or equal to than the cut-off width. In other words, the second region 20 may have a width that allows the lateral high-order mode of the light beam having the Bragg wavelength to be guided. For example, W2 may be 3 μm or more. The total amount of light beams to be generated becomes larger as the mesa width becomes wider, and hence the light output intensity of the semiconductor laser 1 may be increased. For example, the mesa width of the third region 30 be gradually increased from the first region 10 toward the second region 20 so that a smooth connection may be achieved between the first region 10 and the second region 20. That is, the mesa structure of the third region 30 may have a tapered shape of being inclined with respect to the first direction D1 in top view, but the mesa structure of the third region 30 may not be limited thereto. For example, the boundary between the mesa structure of the third region 30 and the buried layer 17 may change linearly or change while including a curve in top view.

In the semiconductor laser 1 according to some implementations of the present invention, even when the mesa width W2 of the second region 20 is equal to or larger than the cut-off width, the light beam output from the facet does not include the lateral high-order mode, and thus the semiconductor laser 1 has an excellent light output characteristic without occurrence of kinks (e.g., that are caused by a lateral high-order mode). This characteristic is achieved because the mesa width W1 of the first region 10 is equal to or smaller than the cut-off width. The laser light beam oscillating inside the semiconductor laser 1 is determined by the entire structure including the first region 10, the second region 20, and the third region 30. Even if a light beam of the lateral high-order mode is generated in the second region 20, this light beam cannot be guided in the first region 10, and hence is not reflected in the first region 10. Accordingly, this light beam cannot exist with a strong intensity in the semiconductor laser 1. Furthermore, a light beam having a lateral basic mode, which may be guided through the first region 10, may also be guided through the second region 20. Accordingly, light beams having the lateral basic mode strengthen each other by being reflected between the first region 10 and the second region 20 so as to be output from the facet as a very strong light beam (so-called laser light beam). Here, in order to sufficiently obtain this effect, there is sufficient suppression of the occurrence of the light beam having the lateral high-order mode in the first region 10. in some implementations, the normalized coupling coefficient κ1L1 of the first region 10 may be required to be larger than the normalized coupling coefficient κ2L2 of the second region 20. For example, κ1L1 be 60% or more (that is, κ2L2 be 40% or less) with respect to the normalized coupling coefficient of the entire semiconductor laser 1. Further, when L1 is increased to increase κ1L1, a ratio with respect to the entire element of the second region 20 for increasing the light output may be decreased. Accordingly, the effect of achieving high output cannot be sufficiently obtained, and hence it may be preferred that κ1L1 be 80% or less. When a higher output characteristic is required, it may be preferred that κ1L1 be 70% or less.

Further, a resonator length of the semiconductor laser 1 may be a total length in the first direction D1 of all of the first region 10, the second region 20, and the third region 30. The first example implementation also increases the light output intensity of the light beam output from the front facet 40 so as to be larger than the light output intensity of the light beam output from the rear facet 50. Accordingly, the first region 10 (e.g., the first diffraction grating region) may be located on the rear side. For example, the first diffraction grating region be arranged in a region within 40% or less of the resonator length from a rear end portion (in this case, the rear facet 50) of the resonator. That is, the length of the first diffraction grating region in the direction in which the mesa structure extends may be less than or equal to 40% of the length of the entire diffraction grating layer, or less than or equal to 30% thereof. In other words, it may be preferred that a leading end Gt of the first diffraction grating region on the third region 30 side be arranged at a position corresponding to 40% or less or 30% or less of the resonator length from the rear side. The above-mentioned numerical value concerning the position of Gt may be as small as practically possible, but κ1L1 is excessively decreased when the numerical value is excessively small. For example, when κ1L1 is smaller than 1, a threshold value of oscillation is increased, which may not be preferred in the viewpoint of power consumption. Accordingly, κ1L1 may be set to 1 or more, such as 1.5 or more.

With the above-mentioned configuration, the semiconductor laser 1 may include the first region 10 and the second region 20 having x-shifted diffraction grating phases which take into consideration the optical path length, and both facets thereof may have the low-reflection facet coating film 4 formed thereon. Thus, the semiconductor laser 1 may have a single mode oscillation. Further, the normalized coupling coefficient κ1L1 of the first region 10 may be larger than the normalized coupling coefficient κ2L2 of the second region 20, and hence the light output intensity of the light beam output from the front facet 40 may be increased. Further, the mesa width W2 of the second region 20 may be wider than the mesa width W1 of the first region 10, and hence, as compared to a semiconductor laser having a structure in which the second region 20 and the first region 10 have the same mesa width, the semiconductor laser 1 according to the first example implementation has a higher output characteristic. In addition, the mesa width W1 of the first region 10 is equal to or smaller than the cut-off width, and hence an excellent light output characteristic without occurrence of the lateral high-order mode, that is, without occurrence of kinks can be achieved.

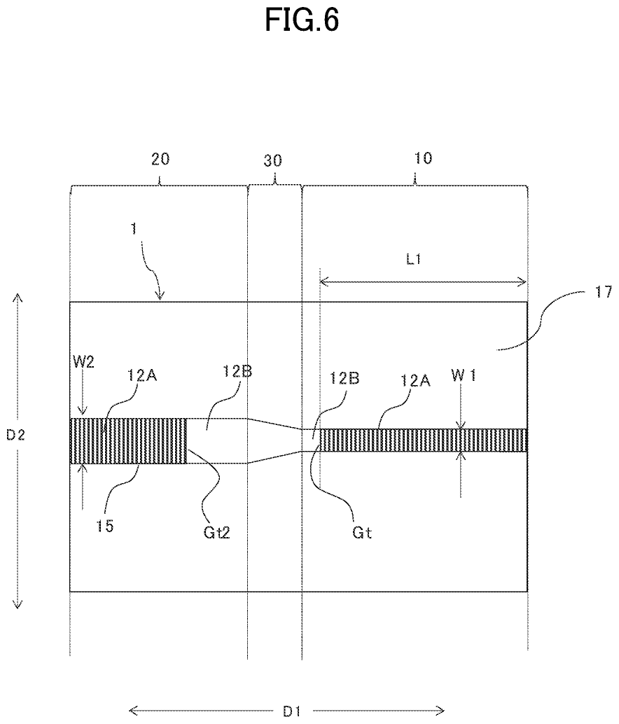

FIG. 6 is a top view for illustrating the semiconductor laser 1 according to a modification example of the first example implementation. FIG. 6 is a view corresponding to FIG. 5. The second region 20 of the semiconductor laser 1 according to the modification example may include one diffraction grating region 12A and one non-diffraction grating region 12B. In this modification example, the length for determining the normalized coupling coefficient of the second region 20 may be the length in the first direction D1 of the one diffraction grating region 12A. Similar to the first example implementation, the normalized coupling coefficient κ2L2 of the second region 20 may be smaller than the normalized coupling coefficient κ1L1 of the first region 10. As described above, in the second region 20, it may not be required to arrange a plurality of diffraction grating regions 12A and non-diffraction grating regions 12B. However, in some implementations, a length from the leading end Gt of the first diffraction grating region to a leading end Gt2 of the second diffraction grating region on the first region 10 side be equal to or smaller than a half of the length of the first diffraction grating region. A region between Gt and Gt2 may be the non-diffraction grating region 12B, and when a length of this non-diffraction grating region 12B is larger than the half of the length of the first region 10, in some cases, oscillation of a wavelength different from the desired Bragg wavelength may be caused. When a plurality of non-diffraction grating regions 12B are included as in the first example implementation, the length of each of all of the non-diffraction grating regions 12B including the third region 30 may be less than or equal to half of the length of the first diffraction grating region, and the total length of the plurality of non-diffraction grating regions 12B may be longer than the length of the first diffraction grating region.

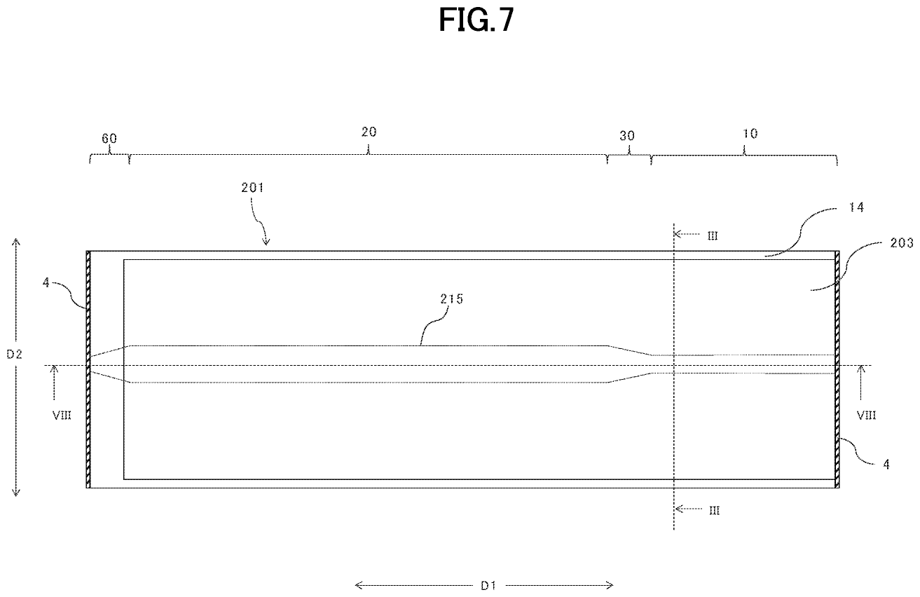

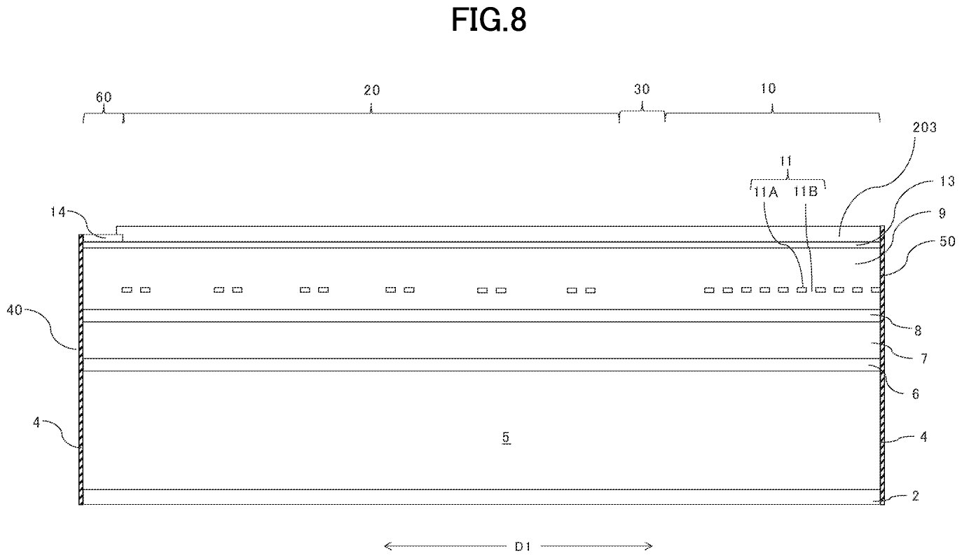

FIG. 7 is a top view for illustrating a semiconductor laser 201 according to a second example implementation of the present invention. FIG. 8 is a schematic sectional view taken along the line VIII-VIII of FIG. 7. The second example implementation may be different from the first example implementation in that the semiconductor laser 201 may include a spot size conversion part 60 between the second region 20 and the front facet 40.

The spot size conversion part 60 may include a semiconductor layer in which, on the substrate 5, the SCH layer 6 of the first conductivity type, the active layer 7, the SCH layer 8 of the second conductivity type, and the cladding layer 9 of the second conductivity type may be grown in the stated order. The insulating film 14 may be arranged on the cladding layer 9 of the second conductivity type. The contact layer 13 may be included between the cladding layer 9 and the insulating film 14. The spot size conversion part 60 does not include the diffraction grating region 12A. In a region having the same height as that of the diffraction grating layer 11, the cladding layer 9 of the second conductivity type, that is, the second refractive index region 11B may be arranged. The spot size conversion part 60 may be also a part of a mesa structure 215. The mesa width at a boundary between the spot size conversion part 60 and the second region 20 may be W2, and the mesa width of the spot size conversion part 60 may be gradually narrowed from W2 toward the front facet 40. The narrowest portion may be a portion in contact with the front facet 40. The mesa width of the spot size conversion part 60 on a side closest to the front facet 40 may be set so that a desired light output shape may be obtained. This mesa width is, for example, smaller than W1. Further, a part of a second electrode 203 enters the spot size conversion part 60, but the second electrode 203 is not limited thereto. The second electrode 203 may be arranged in the entire spot size conversion part 60. Further, the contact layer 13 and the second electrode 203 may be arranged in the spot size conversion part 60.

Also in the second example implementation, the structures of the first region 10 and the second region 20, such as the structure of the diffraction grating layer 11, may be the same as that of the first example implementation, and thus a high-output characteristic, a single mode oscillation, and a kink-free characteristic are achieved.

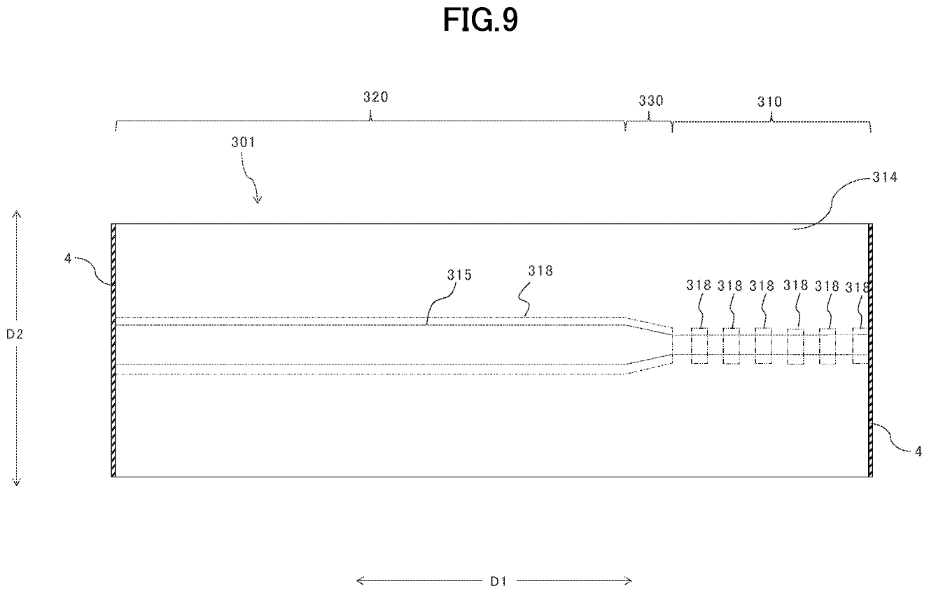

FIG. 9 is a top view for illustrating a semiconductor laser 301 according to a third example implementation of the present invention. The semiconductor laser 301 has the same structure as that of the semiconductor laser 1 of the first example implementation except for a shape of a through hole 318. In FIG. 9, for the sake of description, a position of a mesa structure 315 is indicated by the broken lines, and the position of the through hole 318 is indicated by the dash-dot-dot lines. Further, the second electrode 3 is not shown.

The through hole 318 may be an opening formed through an insulating film 314. In a first region 310, the through hole 318 may be prevented from being arranged in a part of an upper surface of the mesa structure 315. In other words, the through hole 318 may be discretely arranged in the first region 310. That is, in the first region 310, the insulating film 314 may be arranged in a part of the upper surface of the mesa structure 315. In a second region 320 and a third region 330, the through hole 318 may be entirely formed. The second electrode 3 may cover the entire through hole 318.

As described in the first example implementation, the normalized coupling coefficient κ1L1 of the first region 310 may be larger than the normalized coupling coefficient κ2L2 of the second region 320. A boundary between the first region 310 and the third region 330 may be arranged on the rear side (right side of FIG. 9) with respect to a center portion of the semiconductor laser 301. Accordingly, a photon density of the first region 310 may be smaller than a photon density of the second region 320. Consumption of carriers due to stimulated emission becomes larger as the photon density becomes larger, and hence, when the first region 310 and the second region 320 have equal injection current densities, a carrier density of the first region 310 becomes larger than a carrier density of the second region 320. The increase of the carrier density causes deterioration of a characteristic of the semiconductor laser, for example, a relative intensity noise characteristic. The carrier density may be dependent on the injected current amount. In view of the above, in the third example implementation, a region to which currents are injected is may be restricted in the first region 310 so that the increase of the carrier density is reduced. In order to restrict the region to which the currents are injected, the through hole 318 of the first region 310 may be structured to be prevented from being arranged in a part of the upper surface of the mesa structure 315, instead of being arranged in the entire upper surface of the mesa structure 315. In other words, in the upper surface of the mesa structure 315 of the first region 310, opening portions (through hole 318) and non-opening portions (insulating film 314) may be alternately arranged along the first direction D1. No current is injected in a region in which the non-opening portion (insulating film 314) is arranged, and hence the carrier density of the entire first region 310 can be reduced.

A ratio of formation of the opening portion with respect to the entire first region 310 may be 60% or less. in some implementations, in the first region 310, the through hole 318 be arranged in a region of 20% or more and 50% or less of the entire first region 310 in plan view.

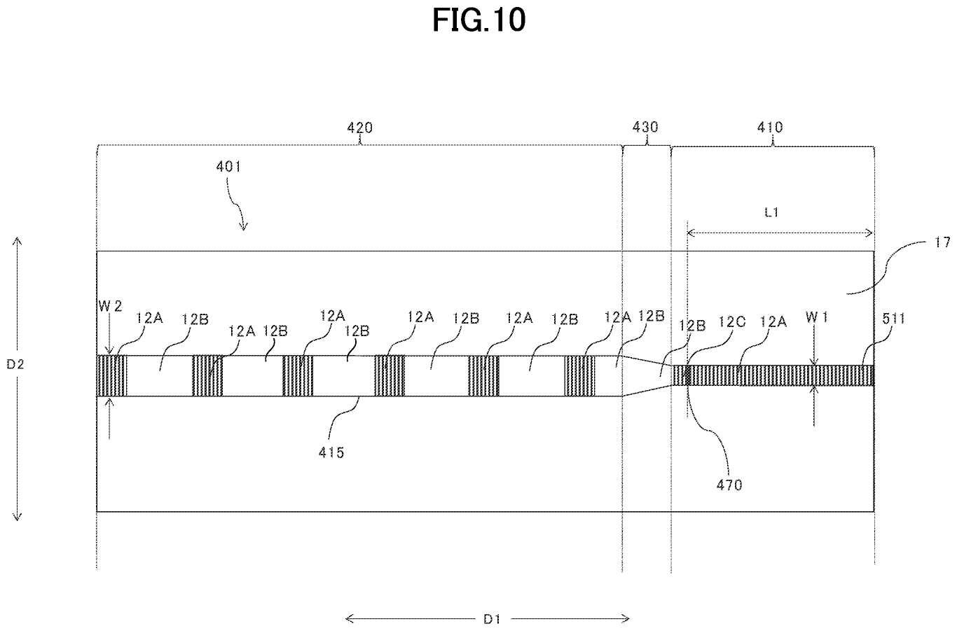

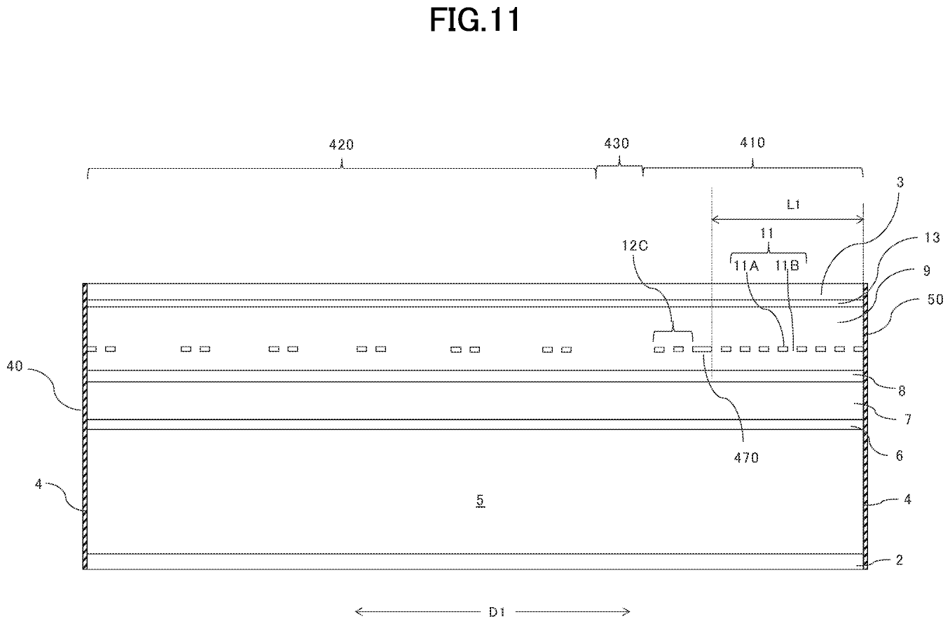

FIG. 10 is a top view for illustrating a semiconductor laser 401 according to a fourth example implementation of the present invention. FIG. 10 corresponds to FIG. 5 in the first example implementation, and shows, for the sake of description, a position of each region included in a diffraction grating layer 511. FIG. 11 corresponds to FIG. 2 in the first example implementation, and is a schematic sectional view taken along a direction in which a mesa structure 415 extends. The fourth example implementation may be different from the first example implementation in that a first region 410 may include a phase shift portion 470. As illustrated in FIG. 11, the phase shift portion 470 may be a λ/4 phase shift portion having a structure in which two first refractive index regions 11A may be continuously arranged (that is, twice as long as other first refractive index regions 11A). In other words, the phase of the diffraction grating structure may be x-shifted between the front and the rear of the phase shift portion 470. The phase shift portion 470 may have a structure in which two second refractive index regions 11B are continuously arranged. Here, a region of the diffraction grating structure, which may be within the first region 410 and may be arranged on a second region 420 side with respect to the phase shift portion 470, may be referred to as “phase shift diffraction grating region 12C.” The first region 410 may include one diffraction grating region 12A having a uniform diffraction grating structure, the phase shift portion 470, and the phase shift diffraction grating region 12C. In FIG. 11, the non-diffraction grating region 12B may be included between the phase shift diffraction grating region 12C and a third region 430, but this non-diffraction grating region 12B may be omitted. Accordingly, the diffraction grating region 12A and the phase shift diffraction grating region 12C of the first region 410 may form a resonator structure across the phase shift portion 470.

The phase of the diffraction grating region 12A of the second region 420 may be the same as the phase of the phase shift diffraction grating region 12C, but may be finely adjusted in consideration of the difference in the optical path length depending on the difference in the effective refractive index caused by the difference in the width of the mesa structure 415. In other words, similar to the first example implementation, the diffraction grating region 12A of the first region 410 and the second region 420 may form a resonator.

In the fourth example implementation, the length L1 of the diffraction grating structure for determining the normalized coupling coefficient κ1L1 of the first region 410 may be the length of the first diffraction grating region (diffraction grating region 12A of the first region 410). Here, the diffraction grating region 12A may be present from the rear facet 50 to the phase shift portion 470. Meanwhile, the length L2 of the diffraction grating structure for determining the normalized coupling coefficient κ2L2 of the second region 420 may be a total length of the plurality of second diffraction grating regions (diffraction grating regions 12A included in the second region 420). Also in the fourth example implementation, κ1L1 may be larger than κ2L2. Further, the width W1 of the mesa structure 415 of the first region 410 may be narrower than the width W2 of the mesa structure 415 of the second region 420. The normalized coupling coefficient of a part of the phase shift diffraction grating region 12C also affects the intensity of the light beam output from the front facet 40. Accordingly, the sum of the normalized coupling coefficient of the phase shift diffraction grating region 12C and the normalized coupling coefficient κ2L2 of the second region 420 may be required to be smaller than the normalized coupling coefficient κ1L1 of the first region 410. For example, the length in the first direction D1 of the phase shift diffraction grating region 12C be ⅕ or less of the length of the diffraction grating region 12A of the first region 410.

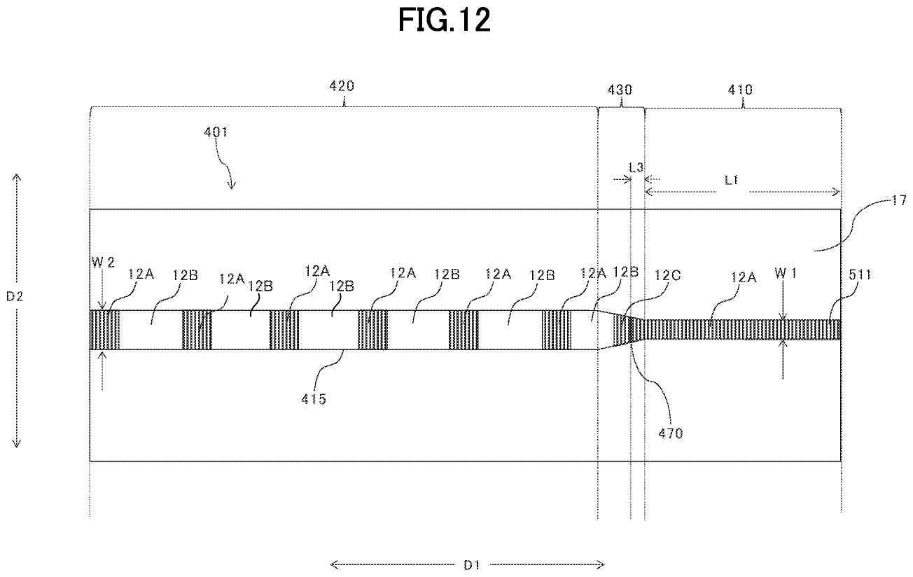

FIG. 12 is a top view for illustrating the semiconductor laser 401 according to a modification example of the fourth example implementation. In this modification example, the phase shift portion 470 may be arranged in the third region 430. As in this modification example, the phase shift portion 470 may not be arranged in the first region 410. Here, in order to increase the intensity of the light beam output from the front facet 40, the normalized coupling coefficient of the rear side (right side of FIG. 12) of the phase shift portion 470 serving as a boundary may be larger than the normalized coupling coefficient of the front side thereof. The normalized coupling coefficient of the rear side may be determined by the length of the diffraction grating region arranged on the rear facet 50 side with respect to the phase shift portion 470. Specifically, the normalized coupling coefficient of the rear side may be determined by the sum of the length L1 of the first diffraction grating region (diffraction grating region 12A of the first region 410) (in this case, the same as the length of the first region) and a length L3 of a region on the first region 410 side with respect to the phase shift portion 470 in the diffraction grating region arranged in the third region 430. Meanwhile, the length of the diffraction grating region for determining the normalized coupling coefficient of the front side may be the length of the phase shift diffraction grating region 12C and a total length of the plurality of diffraction grating regions 12A of the second region 420. However, the length L3 of the diffraction grating region arranged in the third region 430 may be shorter than the diffraction grating region arranged in each of the first region 410 and the second region 420. For example, L3 may be ½ or less as compared to the length (L1) of the first diffraction grating region. Accordingly, also in this modification example, when the normalized coupling coefficient κ1L1 of the first region 410 is set to be larger than the normalized coupling coefficient κ2L2 of the second region 420, the light output intensity of the light beam output from the front facet 40 can be increased.

As described above, the present invention achieves a high output characteristic and a single mode oscillation by forming a resonator by a first region having a narrow mesa width and a second region having a wide mesa width. Further, the mesa width W1 of the first region is set to be equal to or smaller than the cut-off width, and thus the high output characteristic can be obtained while the occurrence of the lateral high-order mode is suppressed. Here, forming the resonator by the first region and the second region represents that the diffraction grating phases which take into consideration the optical path length have a x-shifted relationship. For example, in the first example implementation, the region in which the phase may be x-shifted may be a region between the leading end Gt of the first diffraction grating region and a leading end of the second diffraction grating region on a side closest to the first region 10. The light beam transmitted through the first region 10 may be reflected to the first region 10 side at the second region 20. Similarly, the light beam transmitted through the second region 20 may be reflected to the second region 20 at the first region 10. A portion serving as a boundary of reflection as described above may be the phase shift portion. Further, the regions cause reflection to each other, and hence it may be said that the regions form a resonator. Further, as described in the fourth example implementation, the phase shift portion 470 in which the first refractive index regions 11A or the second refractive index regions 11B may be continuously arranged may be arranged in the diffraction grating layer 11.

The present invention is not limited to the example implementations described above, and various modifications may be made thereto. For example, the configuration described in the example implementations may be replaced by substantially the same configuration, a configuration having the same action and effect, and a configuration that may achieve the same object. Further, the present invention is not limited to a buried type semiconductor laser, and is applicable to a ridge waveguide semiconductor laser as well. The semiconductor laser may be a CW light source or a direct-modulation laser. Further, in the first example implementation to the fourth example implementation, an example in which the width of the mesa structure has two types of W1 and W2 is given, but the width of the mesa structure may have three types or more. Specifically, for example, in the first example implementation, on the front facet 40 side (left facet side of FIG. 1) of the second region 20, a fourth region in which a mesa structure having a width W3 wider than W2 is provided and a fifth region provided between the fourth region and the second region may be provided. Here, similarly to the third region, the fifth region has a mesa width that gradually changes from W2 to W3. With such a configuration, the high light output characteristic can be further improved while the occurrence of the lateral high-order mode is reduced.

According to the present invention, in the semiconductor laser having the mesa structure, a high output characteristic, a single mode oscillation, and reduction in kinks of a lateral mode are achieved. The example implementations of the present invention achieve those characteristics by forming the mesa structure by the first region having a width of W1 and the second region having a width of W2 wider than the width of W1, forming the resonator by the first diffraction grating region of the first region and the second diffraction grating region of the second region, and setting the normalized coupling coefficient of the first region to be larger than the normalized coupling coefficient of the second region. The phases of the diffraction gratings which take into consideration mutual optical path lengths of the first region and the second region are x-shifted. The first region includes the first diffraction grating region in which the first refractive index regions and the second refractive index regions for use in reflecting the light beam having the Bragg wavelength are alternately arranged at the same period. The second region includes the second diffraction grating region in which the first refractive index regions and the second refractive index regions are alternately arranged at the same period, and the non-diffraction grating region which transmits the light beam having the Bragg wavelength. The non-diffraction grating region is formed of only the first refractive index region or only the second refractive index region. The second region includes a plurality of diffraction grating regions and a plurality of non-diffraction grating regions. However, the second region may include one diffraction grating region and one non-diffraction grating region. The plurality of diffraction grating regions and the plurality of non-diffraction grating regions may have lengths different from each other. The width W1 of the mesa structure of the first region may be equal to or smaller than the cut-off width with respect to the light beam having the Bragg wavelength. Further, W1 may be equal to or smaller than 1.5 times the Bragg wavelength. The width W2 of the mesa structure of the second region may be equal to or larger than 1.2 times W1, more preferably 1.5 times W1. The width W2 of the mesa structure of the second region may be equal to or larger than the cut-off width with respect to the light beam having the Bragg wavelength. The normalized coupling coefficient of the first region may be 60% or more of the normalized coupling coefficient of the entire semiconductor laser. The third region in which the width of the mesa structure changes from W1 to W2 may be arranged between the first region and the second region. Further, the semiconductor laser may include the spot size conversion part on the front side of the second region. The diffraction grating layer region may be above or below the active layer. The semiconductor laser may be of a buried type in which the mesa structure is buried in the semiconductor, or of a ridge waveguide type in which the mesa structure is not buried in the semiconductor layer. Further, reduction of the carrier density of the first region allows the characteristics to be improved. In order to reduce the carrier density, the opening ratio of the through hole of the first region is 60% or less, preferably 20% or more and 50% or less. The semiconductor laser of the present invention oscillates at a wavelength of a 1.3-μm band or a 1.55-μm band. However, other wavelength bands may be used.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A semiconductor laser, comprising:
a substrate;
an active layer formed in or under a mesa structure formed on the substrate;
a cladding layer formed above the active layer formed in the mesa structure;
a diffraction grating layer formed in the cladding layer, the diffraction grating layer including a plurality of first refractive index regions and a plurality of second refractive index regions; and
a low-reflection facet coating film provided on both facets in a direction in which the mesa structure extends,
wherein the mesa structure includes, in plan view, a first region having a first width and a second region having a second width that is wider than the first width,
wherein the first region includes a first diffraction grating region in which the plurality of first refractive index regions and the plurality of second refractive index regions for use in reflecting a light beam having a Bragg wavelength are alternately arranged,
wherein the second region includes a second diffraction grating region in which the plurality of first refractive index regions and the plurality of second refractive index regions are alternately arranged, and a non-diffraction grating region which transmits the light beam having the Bragg wavelength,
wherein the first diffraction grating region and the second diffraction grating region form a resonator, and
wherein the first region has a normalized coupling coefficient that is larger than a normalized coupling coefficient of the second region.

2. The semiconductor laser according to claim 1, wherein the first width is equal to or smaller than a cut-off width with respect to the light beam having the Bragg wavelength.

3. The semiconductor laser according to claim 2, wherein the second width is equal to or larger than the cut-off width with respect to the light beam having the Bragg wavelength.

4. The semiconductor laser according to claim 2, wherein the second width is equal to or larger than 1.2 times the first width.

5. The semiconductor laser according to claim 1, wherein the first width is equal to or smaller than 1.5 times the Bragg wavelength.

6. The semiconductor laser according to claim 1, wherein the normalized coupling coefficient of the first region is equal to or larger than 60% of a normalized coupling coefficient of the entire semiconductor laser.

7. The semiconductor laser according to claim 1, wherein the normalized coupling coefficient of the first region is equal to or smaller than 80% of a normalized coupling coefficient of the entire semiconductor laser.

8. The semiconductor laser according to claim 1, wherein the first diffraction grating region has a length in the direction in which the mesa structure extends that is equal to or smaller than 40% of a length of the entire diffraction grating layer.

9. The semiconductor laser according to claim 1, wherein the second diffraction grating region comprises a plurality of second diffraction grating regions, and the non-diffraction grating region comprises a plurality of non-diffraction grating regions.

10. The semiconductor laser according to claim 9, wherein the plurality of second diffraction grating regions and the plurality of non-diffraction grating regions have different lengths in the direction in which the mesa structure extends.

11. The semiconductor laser according to claim 1, wherein the number of second diffraction grating regions and the number of non-diffraction grating regions are each one.

12. The semiconductor laser according to claim 1,
wherein the mesa structure further includes a third region between the first region and the second region, and
wherein the third region has a mesa width that changes from the first width to the second width.

13. The semiconductor laser according to claim 1, further comprising a spot size conversion part,
wherein the spot size conversion part is in contact with the second region,
wherein the spot size conversion part is prevented from including the first diffraction grating region and the second diffraction grating region, and
wherein the mesa structure of the spot size conversion part has a width that is gradually decreased from the second width.

14. The semiconductor laser according to claim 1, wherein the first region includes a non-diffraction grating region on the second region side.

15. The semiconductor laser according to claim 1, further comprising an electrode for use in applying a voltage to the active layer,
wherein the electrode is integrally arranged across the first region and the second region.

16. The semiconductor laser according to claim 1, wherein the first region includes a N4 phase shift portion at a leading end of the first diffraction grating region on the second region side.

17. The semiconductor laser according to claim 1, further comprising a through hole for use in injecting currents to the active layer.

18. The semiconductor laser according to claim 17, wherein the through hole is arranged across the first region and the second region.

19. The semiconductor laser according to claim 17, wherein the through hole is discretely arranged in the first region.

20. The semiconductor laser according to claim 17, wherein, in the first region, the through hole is arranged in a region of 20% or more and 50% or less of the entire first region in plan view.
